(19) United States
(12) Patent Application Publication
(10) Pub. No.: US 2026/0185218 A1
(43) Pub. Date: Jul. 2, 2026

(54) METAL PHOSPHIDE LAYER FOR CONTACT AND METHODS OF FORMING SAME

(71) Applicant: Taiwan Semiconductor Manufacturing Company, Ltd., Hsin-Chu (TW)

(72) Inventors: Olivia Pei-Hua Lee, Hsinchu County (TW); Chia-Hung Chu, Taipei City (TW); Hsin Wang, New Taipei City (TW); Sung-Li Wang, Zhubei City (TW); Jhih-Rong Huang, Zhubei City (TW); Min Cao, Hsinchu (TW)

(21) Appl. No.: 19/203,493

(22) Filed: May 9, 2025

Related U.S. Application Data
(60) Provisional application No. 63/740,160, filed on Dec. 30, 2024.

(51) Int. Cl. C23C 16/42; C23C 16/04; C23C 16/455; H10D 84/01; H10D 84/83; H10D 84/85

(52) U.S. Cl. CPC C23C 16/42; C23C 16/045; C23C 16/45553; H10D 84/017; H10D 84/83125; H10D 84/851

(57) ABSTRACT

A method includes providing a structure. The structure includes an active region having a channel region and a source/drain region adjacent to the channel region, a gate structure over the channel region, a source/drain feature over the source/drain region, a contact etch stop layer (CESL) over the source/drain feature, and an interlayer dielectric (ILD) layer over the CESL. The method further includes forming a trench in the CESL and the ILD layer to expose the source/drain feature, providing a metal precursor and a phosphorus source in the trench, thereby forming a metal phosphide layer over the source/drain feature, forming a silicide layer on the metal phosphide layer, and forming a metal fill layer in the trench.

### PRIORITY DATA

This application claims the benefit of U.S. Provisional Application No. 63/740,160 filed Dec. 30, 2024, the entirety of which is herein incorporated.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, stacked device structures are introduced to enable further density reduction for advanced IC technology nodes. However, fabrication of such stacked device structures introduces more challenges. As a result, existing implementations have not been satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor structure, according to one or more aspects of the present disclosure.

FIGS. 2, 3, 4, 5, 6, 7, 8, and 9 illustrate fragmentary cross-sectional views of an exemplary semiconductor structure during various fabrication stages in the method of FIG. 1, according to one or more aspects of the present disclosure.

FIGS. 10, 11, 12, 13, 14, 15, and 16 illustrate fragmentary cross-sectional views of alternative semiconductor structures during various fabrication stages in the method of FIG. 1, according to one or more aspects of the present disclosure.

FIGS. 17A, 17B, and 17C illustrate exemplary structures of a metal precursor in fabrication of the exemplary semiconductor structures according to the method of FIG. 1, according to one or more aspects of the present disclosure.

FIGS. 18A and 18B illustrate exemplary reactions of forming a metal phosphide layer in fabrication of the exemplary semiconductor structures according to the method of FIG. 1, according to one or more aspects of the present disclosure.

FIG. 19 illustrates a schematic diagram of electric fields at an interface of the exemplary semiconductor structures fabricated according to the method of FIG. 1, according to one or more aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

Stacked transistor structures can provide further density reduction for advanced integrated circuit (IC) technology nodes (particularly as they advance to 3 nm (N3) and below), especially when the stacked transistor structures include multigate devices, such as fin-like field effect transistors (FinFETs), gate-all-around (GAA) transistors including nanowires and/or nanosheets, other types of multigate devices, etc. Stacked transistor structures include vertically stacked transistors. For example, a stacked transistor structure can include a first transistor (i.e., an upper/top transistor) disposed over a second transistor (i.e., a lower/bottom transistor). The transistor stack can provide a complementary field effect transistor (CFET) when the first transistor and the second transistor are of opposite conductivity type (i.e., an n-type transistor and a p-type transistor).

The stacked transistor structures may include source/drain contacts. In some cases, the stacked n-type and p-type transistors share a common source/drain contact. The common source/drain contact may be a local interconnect for connecting n-type and p-type source/drain epitaxial features together. Since the n-type and p-type epitaxial features are stacked vertically one over the other, the local interconnect may need to penetrate through the top epitaxial feature until it lands on the bottom epitaxial feature. However, forming the source/drain contacts in stacked devices involve various challenges, such as higher resistance. Therefore, although existing stacked device structures (e.g., CFET structures) and their related fabrication processes have been generally adequate for their intended purposes, they have not been entirely satisfactory in every aspect.

The present disclosure is generally related to semiconductor structures (e.g., stacked transistor structures) having a source/drain contact. In an example process, a structure (e.g., a CFET structure) is provided. The structure includes a bottom transistor disposed over a substrate and a top transistor disposed over the bottom transistor. The bottom transistor includes a bottom source/drain feature and the top transistor includes a top source/drain feature vertically above the bottom source/drain feature. A trench is formed to expose the bottom source/drain feature and the top source/drain feature. A metal precursor and a phosphorus-containing precursor are deposited in the trench, thereby forming a metal phosphide layer including a first metal over the bottom source/drain feature and the top source/drain feature. A silicide layer including a second metal may be optionally formed on the metal phosphide layer. A metal fill layer is formed in the trench and a planarization process is performed to remove excess materials, thereby forming the source/drain contact. By forming the metal phosphide layer using the method in the present disclosure, resistance of the source/drain contact is reduced. By forming the silicide layer over the metal phosphide layer, an additional dipole layer is formed, and the resistance of the source/drain contact may be further reduced.

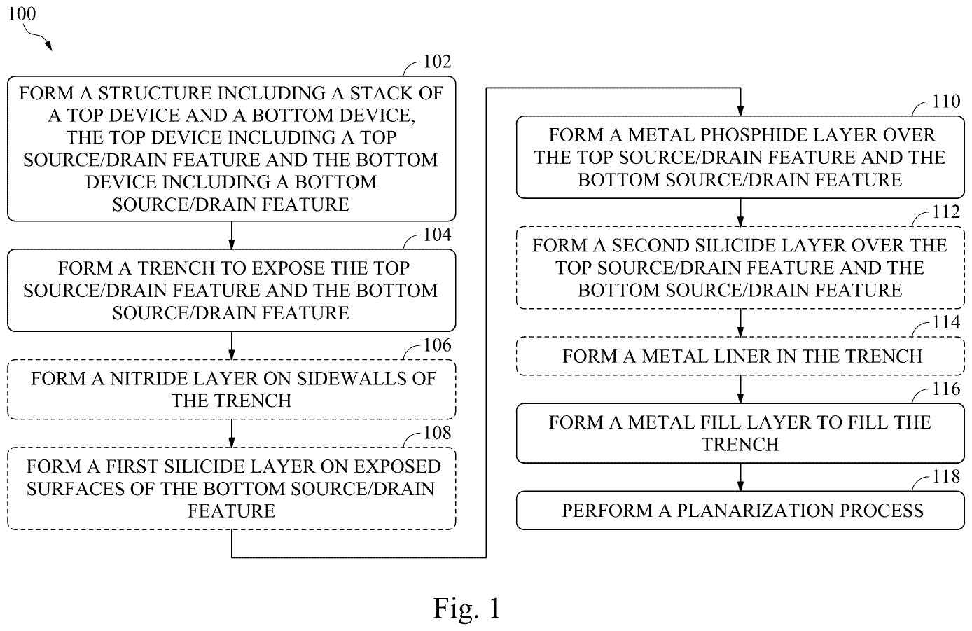

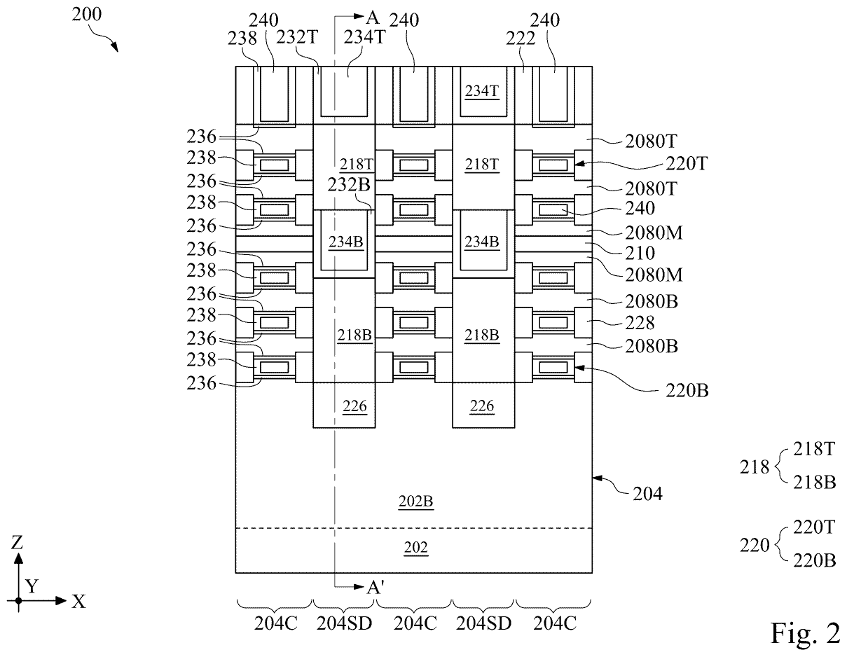

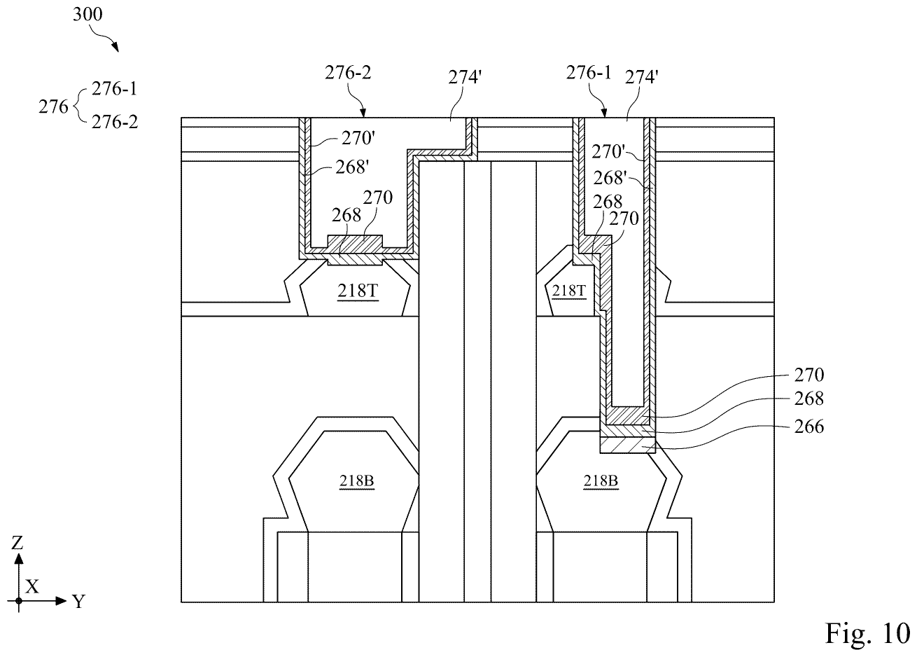

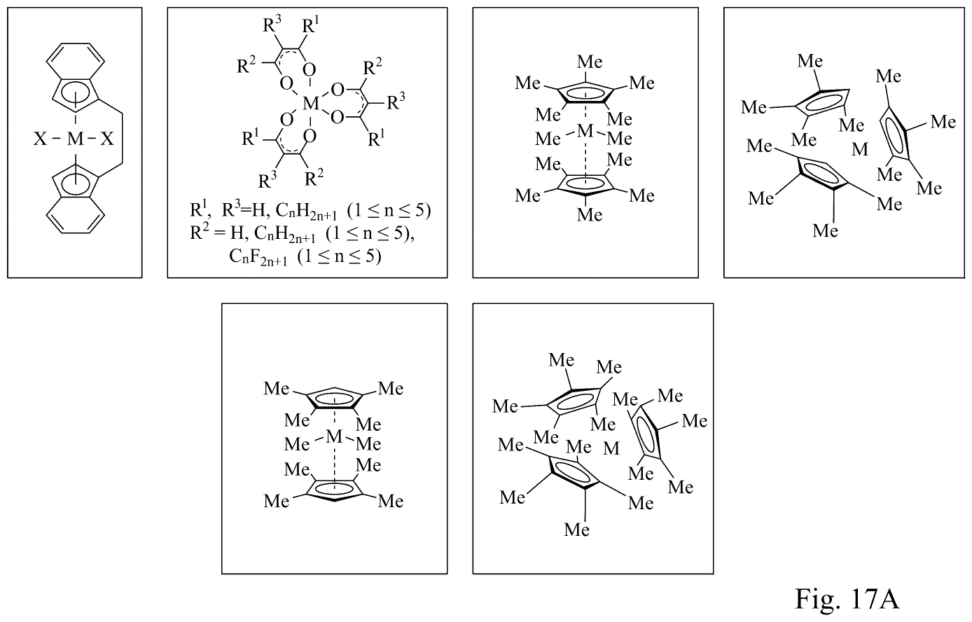

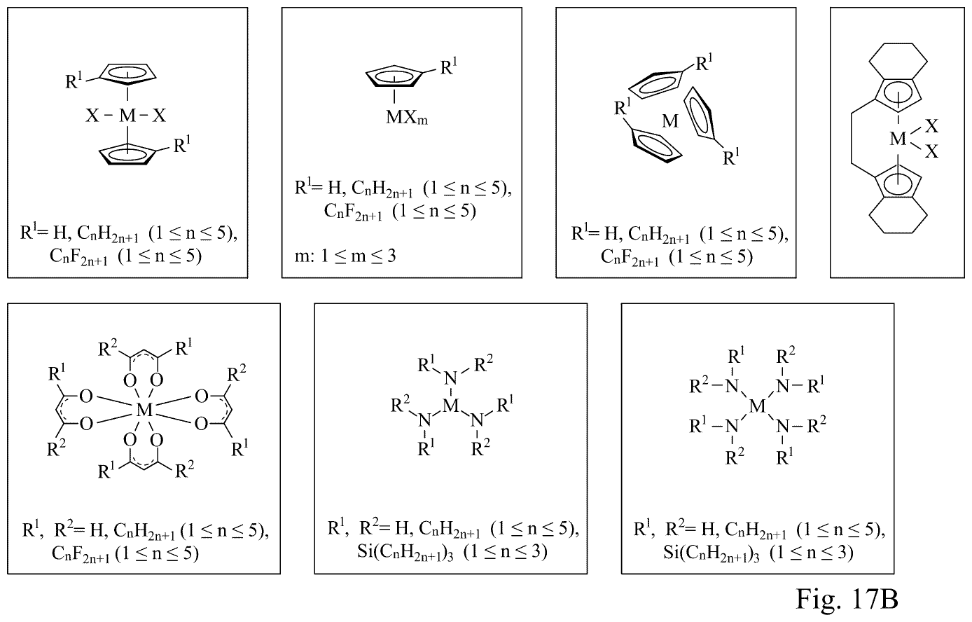

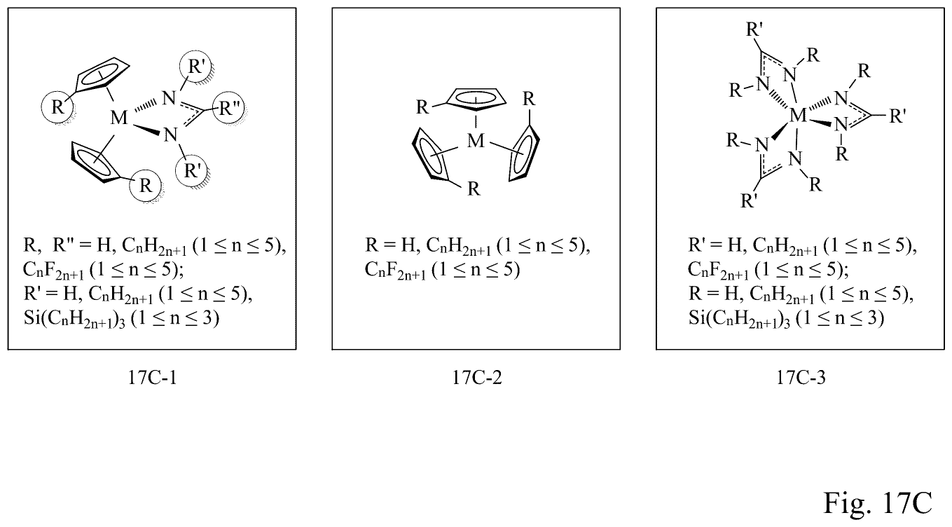

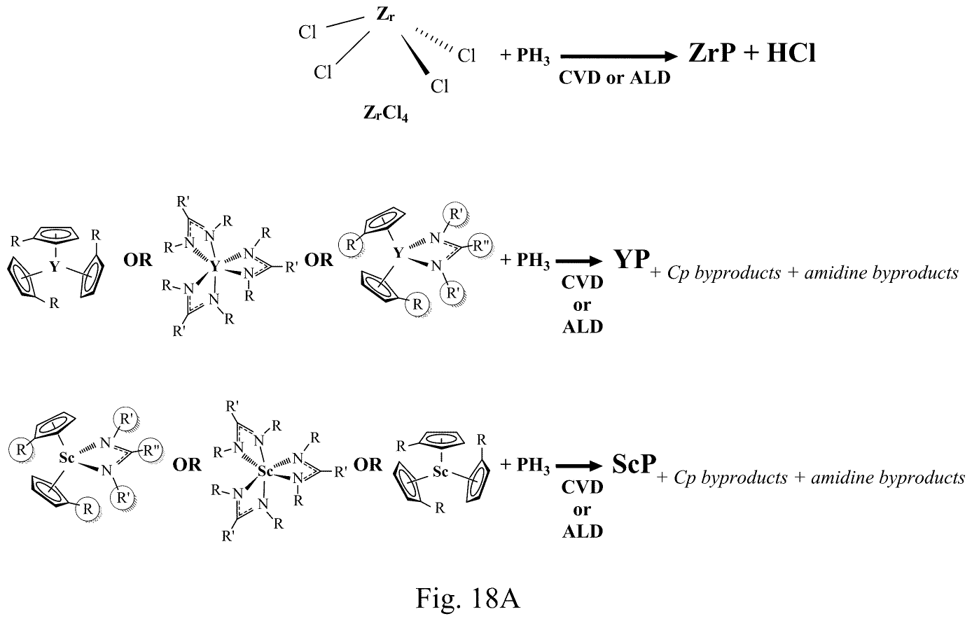

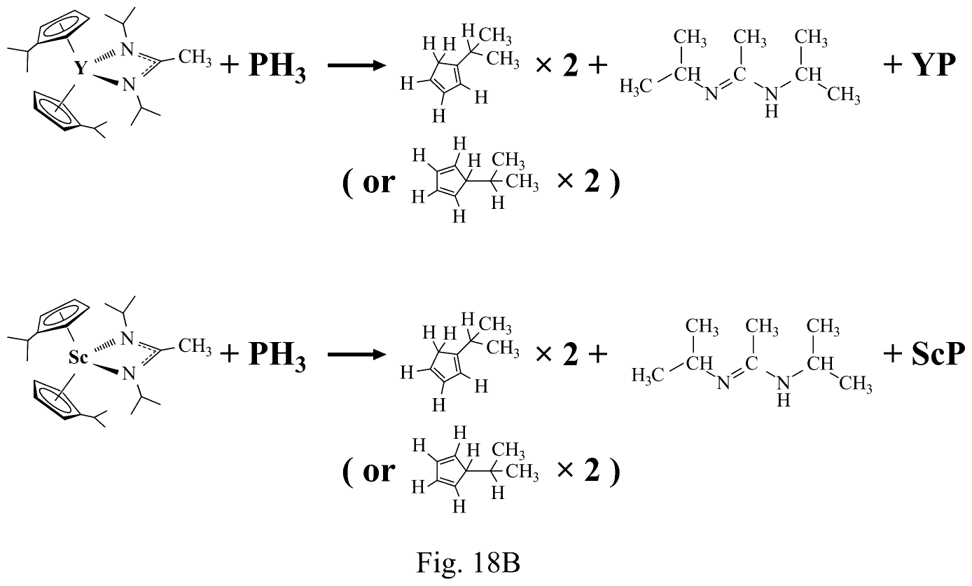

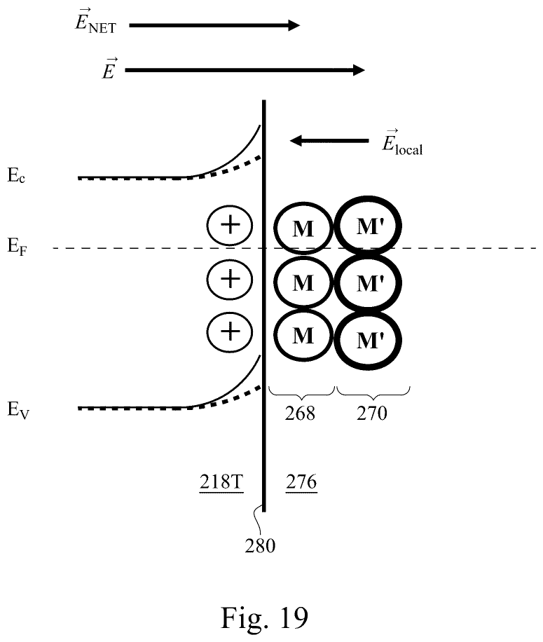

The various aspects of the present disclosure will now be described in more detail with reference to the figures. In that regard, FIG. 1 is a flowchart illustrating method 100 of forming a semiconductor structure according to embodiments of the present disclosure. Method 100 is described below in conjunction with FIGS. 2-22. FIGS. 2-9 are fragmentary cross-sectional views of a structure 200 at different stages of fabrication according to embodiments of method 100 in FIG. 1. FIGS. 10-16 are fragmentary cross-sectional views of alternative structures 300, 400, 500, 200′, 300′, 400′, and 500′, respectively, fabricated according to embodiments of method 100 in FIG. 1. FIGS. 17A-17C illustrate exemplary structures of a metal precursor in fabrication of the exemplary structures according to the method of FIG. 1. FIGS. 18A-18B illustrate exemplary reactions of forming a metal phosphide layer in fabrication of the exemplary semiconductor structures according to the method of FIG. 1. FIG. 19 illustrates a schematic diagram of electric fields at an interface of the exemplary semiconductor structures fabricated according to the method of FIG. 1. Method 100 is merely an example and is not intended to limit the present disclosure to what is explicitly illustrated in method 100. Additional steps can be provided before, during and after method 100, and some steps described can be replaced, eliminated, or moved around for additional embodiments of method 100. Not all steps are described herein in detail for reasons of simplicity. Because the structure 200 (or 300, 400, 500, 200′, 300′, 400′, 500′) will be fabricated into a semiconductor structure, the structure 200 (or 300, 400, 500, 200′, 300′, 400′, 500′) may be referred to herein as a semiconductor structure 200 (or 300, 400, 500, 200′, 300′, 400′, 500′) or a semiconductor device 200 (or 300, 400, 500, 200′, 300′, 400′, 500′) as the context requires. For avoidance of doubts, the X, Y and Z directions in FIGS. 2-16 are perpendicular to one another and are used consistently throughout the present disclosure. Throughout the present disclosure, like reference numerals denote like features unless otherwise excepted. That is, material properties and comparisons thereof for various numbered elements described in association with a method or a figure should apply to the same numbered elements described in association with a different method or a different figure.

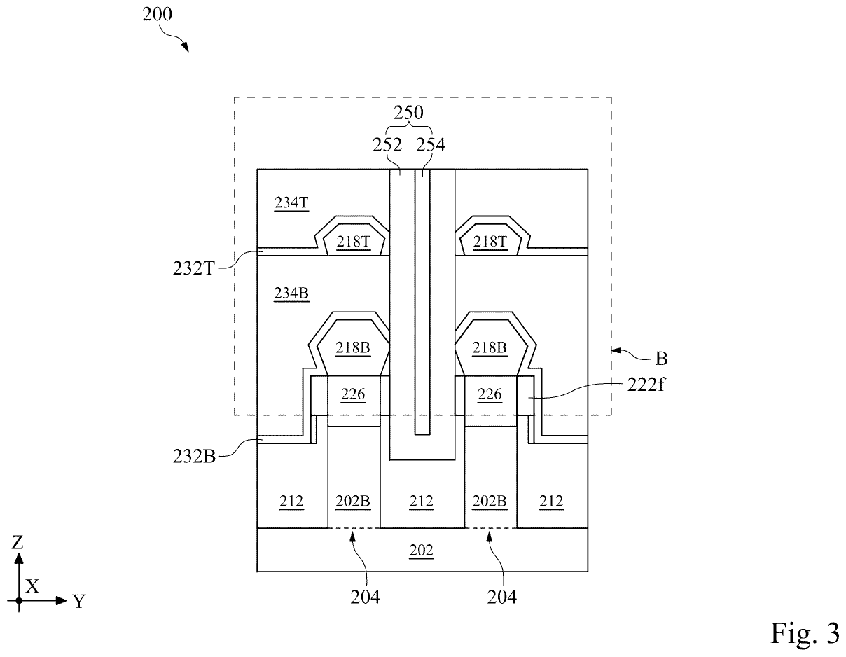

Referring to FIGS. 1-3, method 100 includes a block 102 where a structure 200 is formed or provided. FIG. 3 illustrates a fragmentary cross-sectional view of the structure 200 taken along line A-A′ as in FIG. 2. In some embodiments represented in FIG. 2, the precursor structure 200 includes front-end-of-line (FEOL) CFET structures fabricated on a substrate 202. In the depicted embodiments, the FEOL CFET structures include bottom device structures formed around bottom channel members 2080B and top device structures formed around top channel members 2080T. Along a vertical direction (i.e., the Z-direction), the bottom channel members 2080B are spaced apart from the top channel members 2080T by a middle dielectric layer 210 sandwiched between two middle semiconductor layers 2080M. The bottom channel members 2080B are disposed over a base fin 202B, which is patterned from the substrate 202. An isolation feature 212 (shown in FIG. 3) is disposed over the substrate 202 and surrounds the base fin 202B. The bottom channel members 2080B constitute channel regions that extend horizontally between two bottom source/drain features 218B. Similarly, the top channel members 2080T constitute channel regions extend horizontally between two top source/drain features 218T. The bottom source/drain features 218B and the top source/drain features 218T may be collectively or individually referred to as source/drain feature(s) 218 as the context requires. The bottom device structures include bottom gate structures 220B that wrap around each of the vertical stack of bottom channel members 2080B and the top device structures include top gate structures 220T that wrap around each of the vertical stack of top channel members 2080T. The bottom gate structures 220B and the top gate structures 220T may be collectively or individually referred to as gate structure(s) 220 as the context requires.

Each of the top source/drain features 218T is disposed directly over one of the bottom source/drain features 218B. The bottom source/drain feature 218B may be disposed on a base epitaxial region 226. As shown in FIG. 2, a bottom source/drain feature 218B is spaced apart from an overlying top source/drain feature 218T by a bottom contact etch stop layer (BCESL) 232B and a bottom interlayer dielectric (BILD) layer 234B. The BILD layer 234B is spaced apart from the middle semiconductor layers 2080M and the middle dielectric layer 210 by the BCESL 232B. A top contact etch stop layer (TCESL) 232T and a top interlayer dielectric (TILD) layer 234T are disposed over each of the top source/drain features 218T. The bottom channel members 2080B are stacked one over another along the Z-direction and are interleaved by inner spacer features 228. Similarly, the top channel members 2080T are stacked one over another along the Z-direction and are interleaved by the inner spacer features 228. A gate spacer 222 extends along sidewalls of a portion of the top gate structure 220T above the top channel members 2080T. Due to a planarization process, top surfaces of the TCESL 232T, the TILD layer 234T, the gate spacer 222, and the top gate structures 220T are coplanar. As illustrated in FIG. 2, the bottom channel members 2080B and the top channel members 2080T fall within channel regions 204C of an active region 204 and the bottom source/drain features 218B and the top source/drain features 218T fall within source/drain regions 204SD of the active region 204. A source/drain region 204SD is disposed between two channel regions 204C and a channel region 204C is disposed between two source/drain regions 204SD.

In some embodiments, the substrate 202 may be a silicon (Si) substrate. In some other embodiments, the substrate 202 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 202 may also include an insulating layer, such as a silicon oxide layer, to have a silicon-on-insulator (SOI) structure. The base fin 202B is patterned from the substrate 202 and may share the same composition with the substrate 202. In some embodiments, the bottom channel members 2080B, the middle semiconductor layers 2080M, and the top channel members 2080T may include silicon (Si). The gate spacer 222, the middle dielectric layer 210 and the inner spacer features 228 may include silicon oxide, silicon nitride, silicon oxycarbide, silicon oxycarbonitride, silicon carbonitride, metal nitride, or a suitable dielectric material. The BCESL 232B and the TCESL 232T may include silicon nitride or aluminum nitride. The BILD layer 234B and the TILD layer 234T may include an oxide-based dielectric material, such as silicon oxide, fluorine-doped silicate glass (FSG), a low-k dielectric, combinations thereof, and/or other suitable materials. The BCESL 232B and the TCESL 232T may be thinner than the BILD layer 234B and the TILD layer 234T along the X-direction, respectively. The isolation feature 212 may include an oxide-based dielectric material, such as silicon oxide, fluorine-doped silicate glass (FSG), a low-k dielectric, combinations thereof, and/or other suitable materials.

The base epitaxial regions 226 may include undoped semiconductor material. In the depicted embodiments, the base epitaxial regions 226 include undoped silicon (Si), undoped silicon germanium (SiGe), or undoped germanium (Ge). A top surface of the base epitaxial regions 226 may be at a same level as a top surface of the base fin 202B. The base epitaxial regions 226 may reduce leakage into the substrate 202. In some embodiments, fin spacers 222f are disposed along sidewalls of the base epitaxial regions 226. The fin spacers 222f and the gate spacer 222 may be formed from the same material.

In the embodiments represented in the figures, the bottom source/drain features 218B are p-type and may include silicon germanium (SiGe) doped with a p-type dopant, such as boron (B); the top source/drain features 218T are n-type and may include silicon (Si) doped with an n-type dopant, such as phosphorus (P) or arsenic (As). In these depicted embodiments, the bottom source/drain features 218B may include boron doped silicon germanium (SiGe:B) and the top source/drain features 218T may include phosphorus doped silicon (Si:P). As used herein, source/drain region, source/drain feature, epitaxial source/drain, epitaxial source/drain feature, etc. may refer to a source of a device, a drain of a device, or a source and/or a drain of multiple devices.

In some embodiments, each of the bottom gate structures 220B and the top gate structures 220T includes an interfacial layer 236 to interface the bottom channel members 2080B, the top channel members 2080T, the middle semiconductor layers 2080M, and/or the base fin 202B, a gate dielectric layer 238 over the interfacial layer 236, and a gate electrode 240 over the gate dielectric layer 238. The gate electrode 240 in the bottom gate structure 220B includes a p-type work function layer. The gate electrode 240 in the top gate structure 220T includes an n-type work function layer. In some embodiments, the interfacial layer 236 includes silicon oxide. The gate dielectric layer 238 is formed of high-K dielectric materials. As used and described herein, high-k dielectric materials include dielectric materials having a high dielectric constant, for example, greater than that of thermal silicon oxide (˜3.9). The gate dielectric layer 238 may include hafnium oxide. Alternatively, the gate dielectric layer 238 may include other high-K dielectrics, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. A dielectric constant of the gate dielectric layer 238 is greater than a dielectric constant of the isolation feature 212, the inner spacer features 228, the middle dielectric layer 210, the gate spacer 222, the BCESL 232B, the BILD layer 234B, the TCESL 232T, and the TILD layer 234T. In some instances, the dielectric constant of the gate dielectric layer 238 is more than twice of the dielectric constant of the isolation feature 212, the inner spacer features 228, the middle dielectric layer 210, the gate spacer 222, the BCESL 232B, the BILD layer 234B, the TCESL 232T, or the TILD layer 234T. Further, along the X-direction, a thickness of the gate dielectric layer 238 is smaller than a thickness of the gate spacer 222.

By way of example, the p-type work function layer in the gate electrode 240 of the bottom gate structures 220B may include titanium nitride (TiN), tantalum nitride (TaN), ruthenium (Ru), molybdenum (Mo), aluminum (Al), tungsten nitride (WN), zirconium silicide (ZrSi₂), molybdenum silicide (MoSi₂), tantalum silicide (TaSi₂), nickel silicide (NiSi₂), other p-type work function material, or combinations thereof. The n-type work function layer in the gate electrode 240 of the top gate structures 220T may include titanium (Ti), aluminum (Al), silver (Ag), manganese (Mn), zirconium (Zr), titanium aluminum (TiAl), titanium aluminum carbide (TiAlC), tantalum carbide (TaC), tantalum carbonitride (TaCN), tantalum silicide nitride (TaSiN), tantalum aluminum (TaAl), tantalum aluminum carbide (TaAlC), titanium aluminum nitride (TiAlN), other n-type work function material, or combinations thereof. In one embodiment, gate electrodes 240 in the bottom gate structure 220B and the top gate structure 220T include a titanium-based material.

In some embodiments, referring to FIG. 3, the structure 200 includes a gate isolation structure 250. The gate isolation structure 250 may extend lengthwise along the X-direction in a top view. In the depicted embodiment, the gate isolation structure 250 is disposed between two active regions 204. The gate isolation structure 250 may separate the gate structure 220 into two portions and electrically isolate the two portions. In some embodiments, the gate isolation structure 250 includes silicon nitride, silicon oxide, silicon oxynitride, silicon oxycarbonitride, silicon oxycarbide, silicon carbonitride, or a combination thereof. In one embodiment, the gate isolation structure 250 includes a silicon nitride liner 252 and a dielectric fill 254 surrounded by the silicon nitride liner 252. The dielectric fill 254 may include silicon oxide.

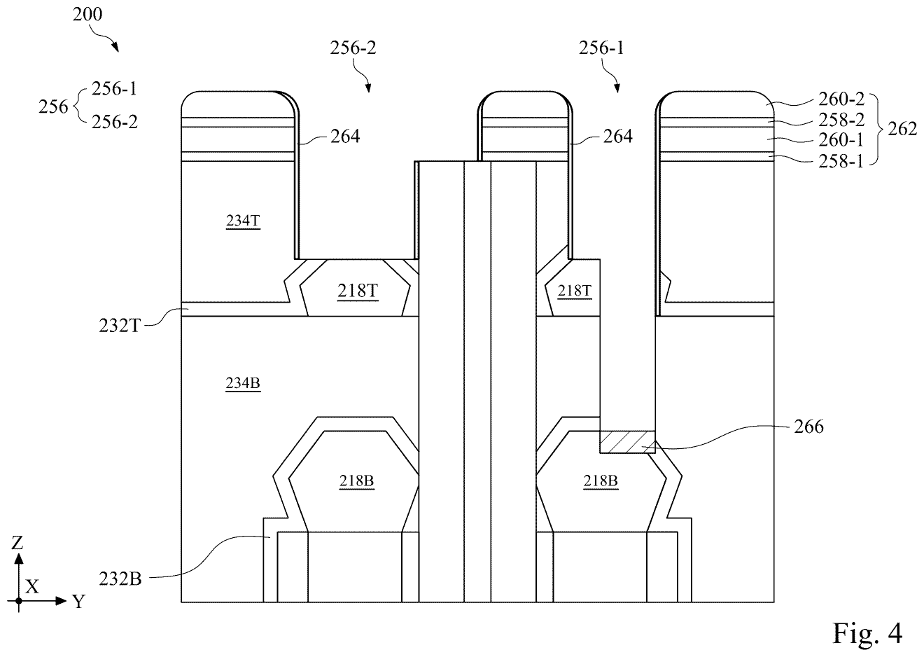

FIGS. 4-9 illustrate fragmentary cross-sectional views of a portion B of the structure 200 in FIG. 3 at different fabrication stages according to method 100. Referring to FIGS. 1 and 4, method 100 includes a block 104 where trenches 256 are formed to expose the source/drain features 218.

The trenches 256 may include a first type trench 256-1 and a second type trench 256-2. The first type trench 256-1 vertically extends through the TILD layer 234T, the BILD layer 234B, the TCESL 232T, and the BCESL 232B to expose both the top source/drain feature 228T and the bottom source/drain feature 218B. A top surface and a sidewall of the top source/drain feature 218T and a top surface of the bottom source/drain feature 218B are exposed in the first type trench 256-1. Thus, the first type trench 256-1 has a first depth to the top surface of the top source/drain feature 218T and a second depth to the top surface of the bottom source/drain feature 218B. The second type trench 256-2 extends through the TILD layer 234T and the TCESL 232T to expose only the top source/drain feature 218T.

In some embodiments, patterning processes are performed to dielectric layers (e.g., the TILD layer 234T, the BILD layer 234B, the TCESL 232T, and the BCESL 232B) to form the trenches 256. In some embodiments, a portion of the top source/drain feature 218T is removed in the patterning processes. The first type trenches 256-1 and the second type trenches 256-2 may be formed in different patterning processes. Forming the first type trench 256-1 may include more than one patterning processes to extend the first type trench 256-1 to the first depth and the second depth. The patterning processes may include a plurality of lithography processes and etching processes. The lithography process may include forming a patterned mask layer 262 over the TILD layer 234T. The patterned mask layer 262 may include multiple dielectric layers, such as an etch stop layer (ESL) 258-1, an ILD layer 260-1, an ESL 258-2, and an ILD layer 260-2 stacked one over another as depicted. The patterned mask layer 262 has openings therein, each of which overlaps a portion of a respective source/drain region 204SD in a top view. The etching process may include transferring a pattern in patterned mask layer 262 to the dielectric layers therebelow and/or the source/drain features 218, for example, by removing portions of the TILD layer 234T, the BILD layer 234B, the TCESL 232T, and the BCESL 232B, and/or the source/drain features 218 exposed by the openings. The etching process may include a dry etch, a wet etch, other suitable etching process, or a combination thereof.

Still referring to FIGS. 1 and 4, method 100 includes a block 106 where a dielectric liner 264 is formed on sidewalls of the trenches 256. Forming the dielectric liner 264 is optional. In FIG. 1, optional blocks are in dashed rectangles with rounded corners.

The dielectric liner 264 may include a dielectric material such as silicon oxide, silicon nitride, silicon carbide, silicon oxynitride, SiCN films, silicon oxycarbide, SiOCN films, and/or combinations thereof. In some embodiments, the dielectric liner 264 includes silicon nitride. By way of example, the dielectric liner 264 may be formed by blanketly depositing a dielectric material layer in a conformal manner over the structure 200 using processes such as, a chemical vapor deposition (CVD) process, a subatmospheric CVD (SACVD) process, an atomic layer deposition (ALD) process, a physical vapor deposition (PVD) process, or other suitable process. In the illustrated embodiment, the deposition of the dielectric material layer is followed by an etching-back (e.g., anisotropically) process to remove the dielectric material layer from horizontal surface(s) and a bottom portion of sidewalls of the trenches 256. In some embodiments, the etching-back process may include a wet etch process, a dry etch process, a multiple-step etch process, and/or a combination thereof. In some embodiments, the etching-back process includes a directional etching process (e.g., a tilted plasma etching), in which an ion beam may be directed to a surface of structure 200 with a tilt angle with respect to the Z-direction. In embodiments, bottom portions of sidewalls of the trenches 256 (e.g., from and below the top source/drain feature 218T) are exposed after the etching-back process. The dielectric material layer may remain on exposed sidewalls of the TILD layer 234T, the TCESL 232T, and the gate isolation structure 250 as the dielectric liner 264. The dielectric liner 264 prevents diffusion between a metal fill layer (to be described below) and the dielectric layers (e.g., the TILD layer 234T, the TCESL 232T). In some embodiments, the deposited dielectric liner 264 is first treated such that its composition is changed. In some examples, the treated portion of the dielectric liner 264 remains during the etching-back process and the untreated portion is removed by the etching-back process. In furtherance of the embodiments, the dielectric liner 264 includes silicon oxide, and the treating process includes a tilted ion implantation using proper ions, such as nitrogen ions so that nitrogen is introduced into a bottom portion of the dielectric liner 264. Thereafter, the treated portion of the dielectric liner 264 is selectively removed by the etching-back process using a proper etchant such as phosphorous acid. In some embodiments, the deposition of the dielectric material layer is before extending the first type trench 256-1 from the first depth to the second depth, and followed by an etching-back (e.g., anisotropically) process to remove the dielectric material layer from horizontal surface(s) (e.g., the top surfaces of the top source/drain features 218T), thereby forming the dielectric liner 264.

Before proceeding to a next process, a cleaning process may be performed to remove any debris from the surfaces in the trenches 256. In some embodiments, the cleaning process includes purging a carrier gas (e.g., an inert gas) to clean the surfaces of the structure 200.

Still referring to FIGS. 1 and 4, method 100 includes a block 108 where a first silicide layer 266 is selectively formed on the exposed surfaces (e.g., the top surface) of the bottom source/drain feature 218B but not the source/drain feature 218T. Block 108 is optional.

The first silicide layer 266 may include silicide, germanide and/or germosilicide of a suitable metal, such as ruthenium, nickel, platinum, palladium, vanadium, titanium, cobalt, tantalum, ytterbium, zirconium, other suitable metal, or a combination thereof. In some embodiments, the first silicide layer 266 includes titanium, silicon, and germanium, and may be referred to as titanium germosilicide.

In some embodiments, selectively forming the first silicide layer 266 on the bottom source/drain feature 218B uses a selective deposition process, such as ALD, plasma enhanced atomic layer deposition (PEALD), CVD, plasma enhanced chemical vapor deposition (PECVD), or metal organic chemical vapor deposition (MOCVD). In such embodiments, resulted from selectivity of the deposition process, the first silicide layer 266 is formed more on exposed surfaces of the bottom source/drain feature 218B than on the other surfaces (e.g., exposed surfaces of the top source/drain feature 218T and the dielectric layers in the trench 256) of the structure 200. In some other embodiments, selectively forming the first silicide layer 266 on the bottom source/drain feature 218B may include a deposition process and a patterning process. In the deposition process, silicide layers are formed on the top source/drain feature 218T and the bottom source/drain feature 218B. A mask layer (e.g. a bottom antireflective coating (BARC) layer) may be deposited and patterned to cover the silicide layer on the bottom source/drain feature 218B. The silicide layer on the top source/drain feature 218T may be removed by a suitable process (e.g., an etching process), and the patterned mask layer is removed, leaving the first silicide layer 266 on the bottom source/drain feature 218B. The first silicide layer 266 may reduce resistance of a source/drain contact (to be described).

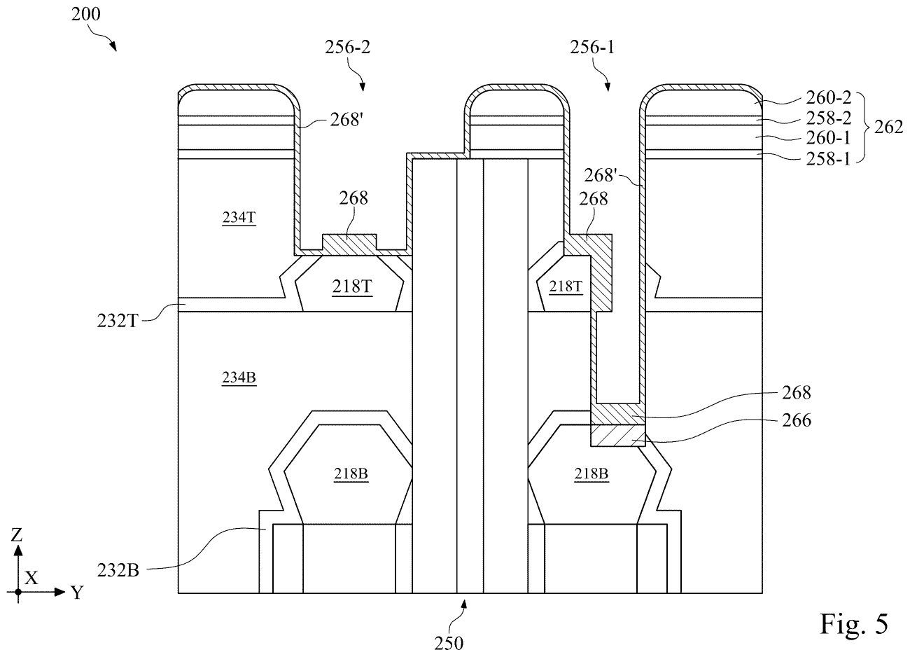

Referring to FIGS. 1 and 5, method 100 includes a block 110 where a metal phosphide layer 268 is formed over the top source/drain feature 218T and the bottom source/drain feature 218B. The dielectric liner 264 is not explicitly depicted in FIG. 5 and subsequent figures for the purpose of simplicity. It is understood that the structure 200 may include the dielectric liner 264 as described above.

Operations at block 110 may include depositing a metal precursor and a phosphorus-containing precursor to the structure 200, including in the trenches 256. Depositing the metal precursor and phosphorus-containing precursor may use processes such as a CVD process, an ALD process. The deposition may be at a temperature of about 100 degree C. to about 600 degree C.

In some embodiments, the metal precursor includes a first metal (M). The first metal may include an early transition metal. In some embodiments, the first metal includes zirconium (Zr), hafnium (Hf), scandium (Sc), yttrium (Y), ytterbium (Yb), lanthanum (La), erbium (Er), dysprosium (Dy), cerium (Ce), or a combination thereof. In some embodiments, the metal precursor includes a metal halide (e.g., fluorides, chlorides, bromides, and iodides) of the first metal, a coordination complex of the first metal, or a combination thereof. The metal halide may have a boiling point, a sublimation temperature, and/or a decomposition temperature of equal to or less than about 500 degree C. For example, the metal halide includes zirconium(III) chloride (ZrCl₃), zirconium(IV) chloride (ZrCl₄), hafnium tetrachloride (HfCl₄), zirconium(IV) bromide (ZrBr₄), hafnium tetrabromide (HfBr₄), or a combination thereof. The range of the boiling point, the sublimation temperature, and/or the decomposition temperature is not randomly chosen but rather specifically configured to facilitate the following processes. In some embodiments, the coordination complex includes a coordination center of the first metal and ligands surrounding the coordination center. In some embodiments, the ligands are independently selected from tris-alkylcyclopentadienyl, bis-alkylcyclopentadienyl-alkylamidinate, tris-alkyl amidinate, tris-(alkylacac), tris[N,N-bis(trimethylsilyl)amide], tetrakis(dialkylamido), and cyclopentadienyl metal chlorides. FIGS. 17A-17C illustrate some examples of the metal precursor. In FIGS. 17A-17C, M is the first metal, Me is methyl group, X is a halogen atom (e.g., F, Cl, Br, I). Groups R, R¹, R², R³, R′, R″ are specified under respective structures, where “=” refers to being independently selected from. Each occurrence of a subscript variable (e.g., n, m) in any structure or group provided herein can be independently selected from a respective range provided herein. For example, in a same structure 17C-1 in FIG. 17C, n in groups R, R′, and R″ may each be independently selected from a respective range of n provided below the structure 17C-1. For example, in different structures 17C-1 and 17C-2 in FIG. 17, n in group R of structure 17C-1 and n in group R of structure 17C-2 may each be independently selected from a respective range of n provided below the respective structure for group R. In the structures in FIG. 17C, in some examples, M is Y, Sc, or La.

In some embodiments, the phosphorus-containing precursor includes phosphorus (P), phosphine (PH₃), diphosphine (P₂H₄), PₙHₙ₊₂ (phosphines, phosphanes, phosphenes), P(SiH₃)₃, P(Si(CₙH₂ₙ₊₁)₃)₃, P(CₙH₂ₙ₊₁)₃, P(CₙH₂ₙ₋₁)₃, triphenyl phosphine, tri(2-furyl)phosphine, white phosphorus (P₄), or a combination thereof. Each occurrence of a subscript variable (e.g., n) in any chemical formula provided in this disclosure can be independently selected from a respective range provided herein. For example, n in PₙHₙ₊₂, n in P(Si(CₙH₂ₙ₊₁)₃)₃, n in P(CₙH₂ₙ₊₁)₃, and n in P(CₙH₂ₙ₋₁)₃, may each be independently selected from a respective range of n provided below. In PₙHₙ₊₂, n may be equal to or less than about 3. In P(Si(CₙH₂ₙ₊₁)₃)₃, n may be equal to or less than about 8. In P(CₙH₂ₙ₊₁)₃, n may be equal to or less than about 8. In P(CₙH₂ₙ₋₁)₃, n may be equal to or greater than about 5 and equal to or less than about 8. In some embodiments, n is an integer.

In some embodiments, the metal precursor and the phosphorus-containing precursor react to form a metal phosphide as a reaction (1) below. The byproduct may be any product of the reaction (1) other than the metal phosphide, such as hydrogen chloride (HCl), an amidine, a compound having cyclopentadienyl.

$$metal precursor + phosphorus - containing precursor \to metal phosphide + byproduct \qquad ( 1 )$$

In some embodiments, Gibbs-free energy of the reaction (1) is less than zero. In some embodiments, Gibbs-free energy of the reaction (1) is less than about −1.0 eV. Thus, the reaction (1) is spontaneous. The metal phosphide layer 268 may be formed under the operation conditions (e.g., the temperature). The reaction (1) may include a surface reaction at the exposed surfaces of the source/drain features 218 and/or the first silicide layer 266. FIGS. 18A and 18B illustrate some examples of the reaction (1). Cp may refer to cyclopentadienyl.

In addition to the reaction (1), constituents (e.g., silicon) of the source/drains features 218 may react with the metal phosphide. Therefore, in some embodiments, the metal phosphide layer 268 includes the metal phosphide (MₓP_{z}) of the first metal, a metal silicon phosphide (MₓSi_{y}P_{z}) of the first metal, or a combination thereof. In some embodiments, x is equal to or greater than about 1, and equal to or less than about 15. y may be equal to or greater than zero, and equal to or less than about 30. z may be greater than zero, and equal to or less than about 12. In some embodiments, a ratio of y to x is equal to or less than about 2. In some embodiments, a ratio of z to x is equal to or less than about 1. x, y, and z may be integers. The metal phosphide layer 268 on the top source/drain features 218T may include MₓP_{z} and/or MₓSi_{y}P_{z}. The metal phosphide layer 268 over the bottom source/drain features 218B may include MₓP_{z}. In some embodiments, the metal phosphide layer 268 includes impurities (e.g., carbon, nitrogen) detectable by x-ray photoelectron spectroscopy (XPS) or secondary ion mass spectrometry (SIMS). The impurities may have a concentration of about 0.001% to about 3.0%.

Lattice of the materials (e.g., MₓP_{z}, MₓSi_{y}P_{z}) of the metal phosphide layer 268 may match lattice of the materials (e.g., silicon) of the source/drain features 218, thus reducing resistance of the source/drain contact (to be described). In some embodiments, conduction band of the materials of the metal phosphide layer 268 match conduction band of the materials (e.g., silicon) of the source/drain features 218, which may reduce the resistance of the source/drain contact. The metal phosphide layer 268 may be formed conformally over the source/drain features 218. The term “conformally” may be used herein for ease of description of a layer having substantially uniform thickness over various regions. In some embodiments, the various regions herein include the exposed surfaces of the top source/drain feature 218T and the exposed surfaces of the first silicide layer 266 over the bottom source/drain feature 218B. The conformal forming of the metal phosphide layer 268 may increase interfacial areas between the metal phosphide layer 268 and the features therebelow (e.g., the source/drain features 218 and/or the first silicide layer 266), thus reducing the resistance of the source/drain contact.

Various parameters of the processes (e.g., the ALD process, the CVD process) may be tuned to achieve designed composition and thickness of the metal phosphide layer 268, such as composition of the gases, the temperatures, the time durations, pressures, gas flow rates, source power, bias power, bias voltage, other suitable parameters, or combinations thereof.

The phosphorus-containing precursor provides phosphorus source to form the metal phosphide layer 268, thus phosphorus consumption from the source/drain features 218 (e.g., doped phosphorus in the top source/drain feature 218T) may be avoided or mitigated. In some embodiments, the top source/drain feature 218T includes doped phosphorus from the forming of the top source/drain feature 218T. Concentration of the doped phosphorus at the surface of the top source/drain feature 218T interfacing the metal phosphide layer 268 may maintain or increase during the forming of the metal phosphide layer 268.

In the depicted embodiment, the deposition process further forms a metal phosphide residual layer 268′ on exposed surfaces (e.g., sidewalls, top surfaces) of dielectric materials (e.g., the nitride layer 264, the TCESL 232T, the BCEL 232B, the TILD layer 234T, the BILD layer 234B, and/or the gate isolation structure 250) in the trenches 256. The metal phosphide residual layer 268′ may include the metal phosphide (MₓP_{z}) of the first metal as described above. In some embodiments, the metal phosphide residual layer 268′ is thinner than the metal phosphide layer 268. This may result from selectivity (e.g., epitaxy-to-dielectric selectivity) of the deposition process and/or a first pull-back process (e.g., a sidewall pull-back process) after the deposition process. In some embodiments, the metal precursor and the phosphorus-containing precursor are selectively deposited more over the source/drain features 218 than over the dielectric materials in the trenches 256, thus metal phosphide is formed more over the source/drain features 218 than over the dielectric materials in the trenches 256. In some embodiments, the first pull-back process includes an etching process. In some embodiments, the first pull-back process includes flowing a halide gas (e.g., chlorine, metal chloride, hydrogen chloride) over the structure 200 to reduce a thickness of the metal phosphide on the dielectric materials in the trenches 256, thereby forming the metal phosphide residual layer 268′. The first pull-back process may be after the deposition process.

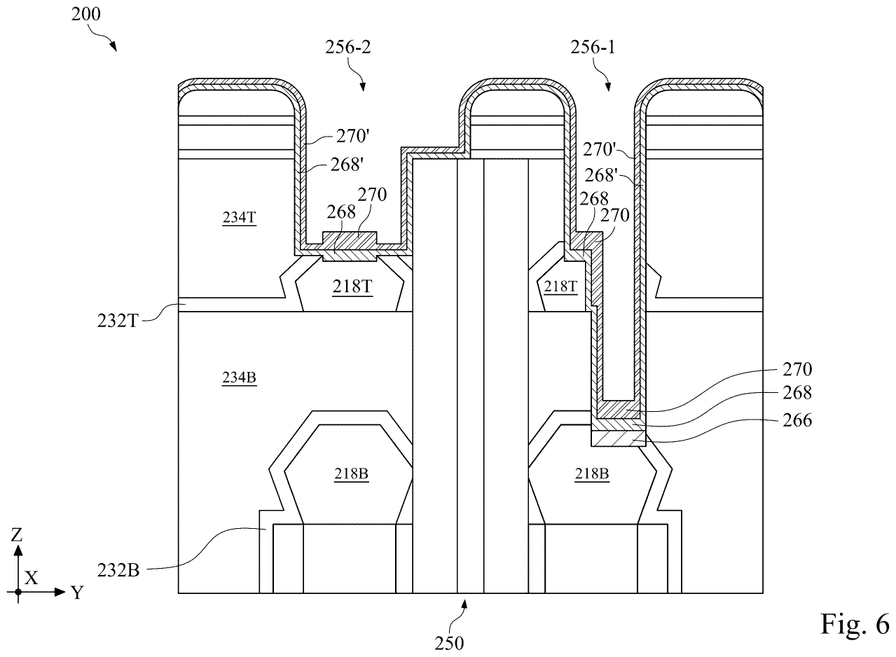

Referring to FIGS. 1 and 6, method 100 includes a block 112 where a second silicide layer 270 is formed over the metal phosphide layer 268.

Operations at block 112 may include depositing a second metal (M′) and optionally a silicon-containing gas to the structure 200 (e.g., including in the trenches 256) using a suitable deposition process, such as a CVD process, an ALD process. The deposition process may be at a temperature of about 100 degree C. to about 600 degree C., alternatively about 350 degree C. to about 600 degree C. The second metal may include titanium (Ti), zirconium (Zr), vanadium (V), niobium (Nb), tantalum (Ta), molybdenum (Mo), tungsten (W), rhenium (Re), ruthenium (Ru), osmium (Os), nickel (Ni), platinum (Pt), palladium (Pd), zinc (Zn), or a combination thereof. In some embodiments, the second metal is different from the first metal. In some embodiments, an electronegativity of the second metal is greater than an electronegativity of the first metal. The silicon-containing gas may include silane (SiH₄), disilane (Si₂H₆), other suitable gases, or a combination thereof. The second silicide layer 270 may include the second metal and silicon and be referred to as a metal silicide of the second metal. In some embodiments, the second silicide layer 270 includes TiSi, NiSi, CoSi, or a combination thereof. In some embodiments, the second metal and the silicon-containing gas form the second silicide layer 270. In some embodiments, constituents (e.g., silicon) of the source/drains features 218 diffuse through the metal phosphorus layer 268 and react with the second metal to form the second silicide layer 270. The second silicide layer 270 may include a metal silicide M′ₓSi_{y}. In M′ₓSi_{y}, x is equal to or greater than about 1 and equal to or less than about 15, y is greater than 0 and equal to or less than about 30. In some embodiments, a ratio of y to x is equal to or less than about 2.

In some embodiments as depicted in FIGS. 5 and 6, a profile of the metal phosphorus layer 268 may change after the forming of the second silicide layer 270. This may result from the diffusion (e.g., of silicon, metal) at the temperature of the deposition process as described above. In such embodiments, the metal phosphorus layer 268 takes up a portion of the original source/drain features 218T (e.g., as in FIG. 4). In some other embodiments, the metal phosphorus layer 268 is disposed on exposed surfaces of the original source/drain features 218T (e.g., as in FIG. 4). In some embodiments, the metal phosphide layer 268 over the source/drain features 218 has a first thickness of about 0.5 nm to about 8 nm. The second silicide layer 270 over the source/drain features 218 and the metal phosphide layer 268 may have a second thickness of about 3 nm to about 10 nm. In some embodiments, a ratio of the second thickness to the first thickness is about 0.5 to about 20. Various parameters of the operations (e.g., the ALD process, the CVD process) may be tuned to achieve designed composition and thickness of the second silicide layer 270, such as composition of the gases, the temperatures, the time durations, pressures, gas flow rates, source power, bias power, bias voltage, other suitable parameters, or combinations thereof.

In the depicted embodiment, the deposition process further forms a metal silicide residual layer 270′ on the metal phosphide residual layer 268′ over the surfaces (e.g., sidewalls) of the dielectric materials of the trenches 256. The metal silicide residual layer 270′ may include the second metal and/or the metal silicide of the second metal as described above. A first total thickness of the metal phosphide residual layer 268′ and the metal silicide residual layer 270′ may be equal to or less than about 2 nm. If the first total thickness is too large (e.g., greater than about 2 nm), integrity of the source/drain contact may be reduced, and following planarization process and reliability of the structure 200 may be impacted. In some embodiments, the first total thickness is less than a second total thickness of the metal phosphide layer 268 and the second silicide layer 270. This may result from selectivity (e.g., epitaxy-to-dielectric selectivity) of the deposition processes at block 110 as described above and at block 112, the first pull-back process at block 110, and/or a second pull-back processes at block 112. In some embodiments, precursors (e.g., the second metal, the silicon-containing gas) and process parameters of the deposition process at block 112 are selected, such that the second metal and/or the metal silicide of the second metal is formed more over the source/drain features 218 than over the dielectric materials in the trenches 256. The second pull-back process may be similar to the first pull-back process. In some embodiments, the second pull-back process removes a portion of the second metal and/or the metal silicide over the dielectric materials in the trenches 256, thus reducing a thickness of the second metal and/or the metal silicide, thereby forming the metal silicide residual layer 270′. The second pull-back process may be after the deposition processes at block 112.

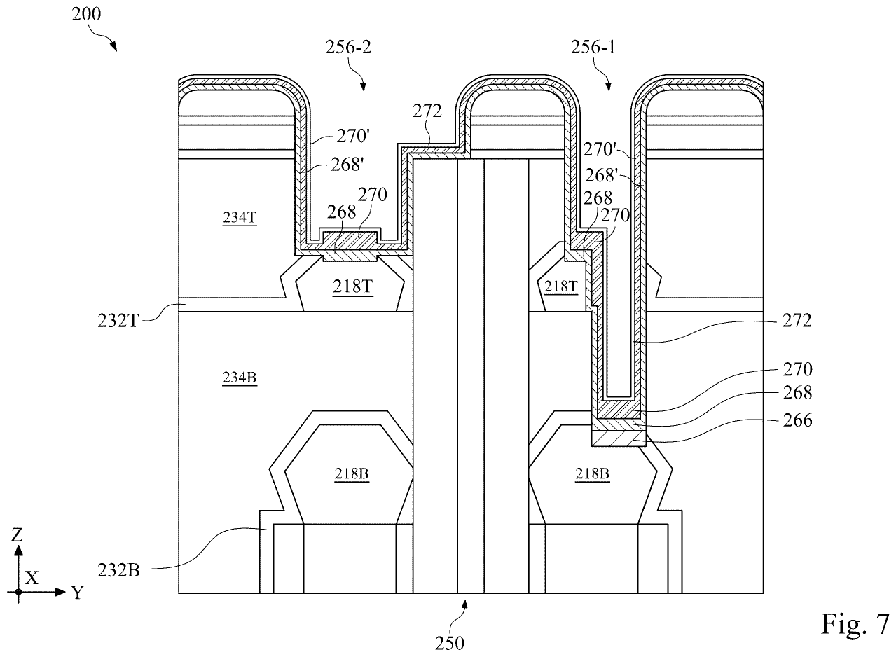

Referring to FIGS. 1 and 7, method 100 includes a block 114 where a metal liner 272 is formed in the trenches 256. The metal liner 272 is conformally deposited over the structure 200, including over the second silicide layer 270 and the metal silicide residual layer 270′. The metal liner 272 may have a thickness of equal to or less than about 2 nm. In some embodiments, the metal liner 272 includes nitride or silicon nitrides of Ti, Zr, Hf, Sc, Y, Yb, La, Er, Dy, Ce, or a combination thereof. For example, the metal liner 272 includes TiN, TiSiN, ScN, ScSiN. The metal in the metal liner 272 may be the same or different from the first metal in the metal phosphide layer 268. The metal liner 272 may prevent diffusion and/or reaction of constituents between adjacent layers and/or promote adhesion between adjacent layers. In some embodiments, the metal liner 272 reduces electromigration of a metal fill layer to be formed thereon and slows down oxygen diffusion into the metal fill layer.

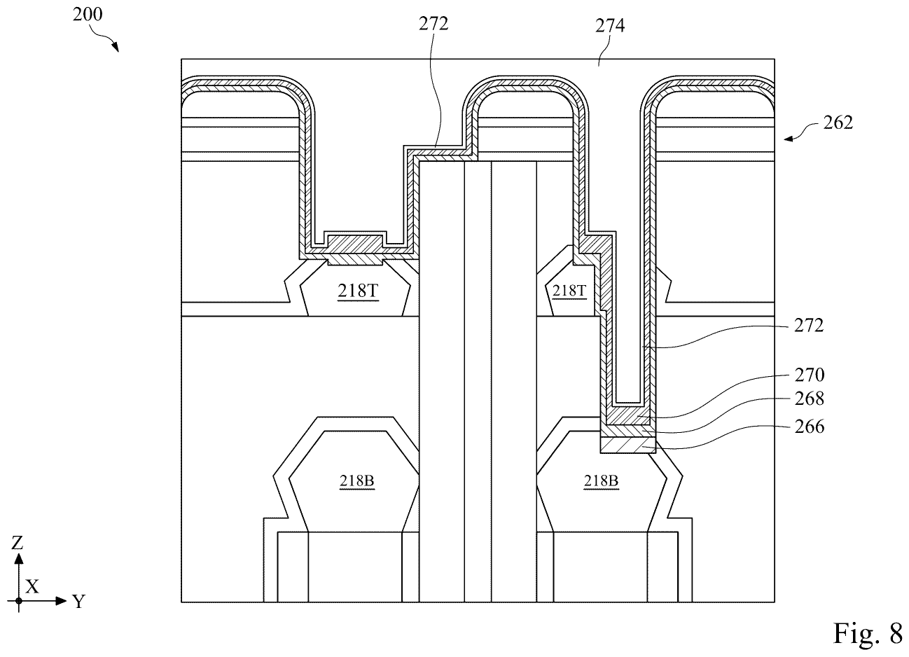

Referring to FIGS. 1 and 8, method 100 includes a block 116 where a metal fill layer 274 is formed over the structure 200 to fill the trenches 256. The metal fill layer 274 may be deposited over the patterned mask layer 262. The metal fill layer 274 may include aluminum (Al), W, Mo, Co, Ru, Re, rhodium (Rh), iridium (Ir), Pt, Ni, Pd, other metals, or alloys thereof (e.g. NiAl, NiRu). In some embodiments, the metal fill layer 274 includes W. An electrical conductivity of the metal fill layer 274 is greater than an electrical conductivity of the source/drain features 218. In some embodiments, the metal fill layer 274 is formed by CVD, PVD, metalorganic CVD (MOCVD), plating, or other suitable processes.

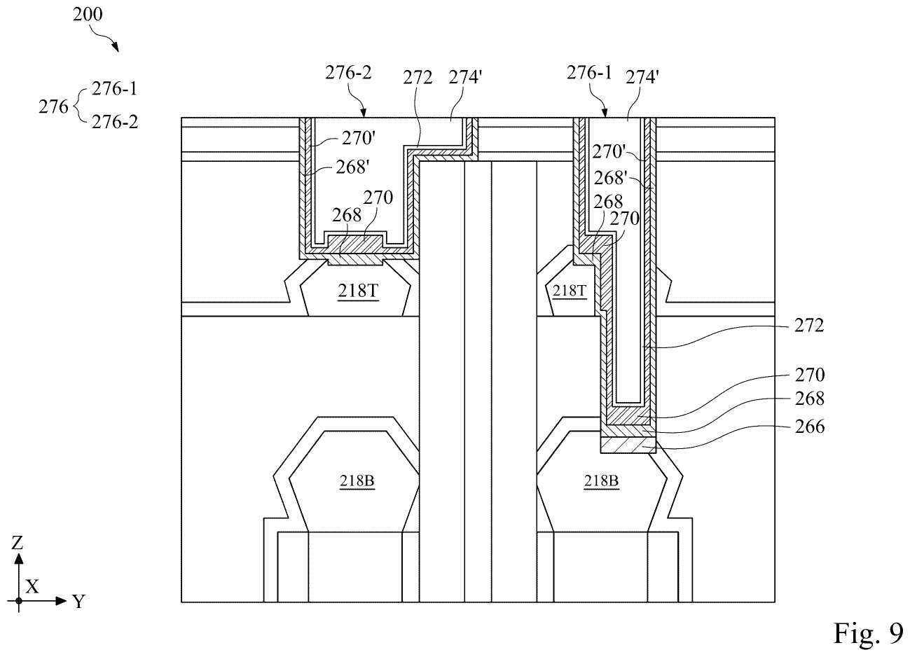

Referring to FIGS. 1 and 9, method 100 includes a block 118 where a planarization process (e.g., a CMP process) is performed to remove excess materials. The planarization process may remove a top portion of the patterned mask layer 262. After the planarization, source/drain contact plugs 274′ are formed from the remaining metal fill layer 274. The source/drain contact plug 274′, the metal liner 272, the first silicide layer 266, the metal phosphide layer 268, the second silicide layer 270, the metal phosphide residual layer 268′, and the metal silicide residual layer 270′ in the first type trench 256-1 collectively form a first source/drain contact 276-1. The source/drain contact plug 274′, the metal liner 272, the metal phosphide layer 268, the second silicide layer 270, the metal phosphide residual layer 268′, and the metal silicide residual layer 270′ in the second type trench 256-2 collectively form a second source/drain contact 276-2. The first source/drain contact 276-1 and the second source/drain contact 276-2 may be collectively or individually referred to as the source/drain contact(s) 276 as the context requires.

The metal phosphide layer 268 and the second silicide layer 270 may form an additional dipole layer over the source/drain features 218, thus reducing resistance of the source/drain contacts 276. FIG. 19 illustrates a schematic diagram at an interface 280 between an n-type source/drain feature 218 (e.g., the top source/drain feature 218T) and the source/drain contact 276. Vector E is an electric field formed from first dipoles. The first dipoles are formed by the top source/drain feature 218T and the second silicide layer 270 without the metal phosphide layer 268. Vector E_{local} is an electric field formed from second dipoles. The second dipoles are formed by the metal phosphide layer 268 and the second silicide layer 270. The first dipoles and the second dipoles are piled up. Vector E_{NET} is a sum electric field of the vector E and the vector E_{local}. Because the second dipoles have a reverse dipole moment to a dipole moment of the first dipoles, the vector E_{local} is in an opposite direction to the vector E as depicted, thus magnitude of the E_{NET} is less than magnitude of the vector E. E_{C} is edge of conduction band, E_{F} is energy of Fermi level, and E_{V} is valence bandage. The solid curves and dashed curves represent E_{C}/E_{V} near the interface 280 in the top source/drain feature 218T before and after the vector E is compensated by (e.g., summed up with) the vector E_{local}, respectively. E_{C}/E_{V} at the interface 280 are reduced after the vector E is compensated by the vector E_{local}. As described above, by having the metal phosphide layer 268 and the second silicide layer 270, electric field at the interfaces is reduced, interfacial Schottky Barrier height (SBH) is reduced, and the resistance of the source/drain contacts 276 is further reduced.

The structure 200 may undergo further processes to form various features and regions known in the art. For example, subsequent processing may form additional interlayer dielectric (ILD) layer(s), contacts/vias/lines and multilayers interconnect features (e.g., metal layers and interlayer dielectrics) over the substrate 202, configured to connect the various features to form a functional circuit that may include one or more devices including the semiconductor device 200. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure.

FIGS. 10-16 illustrates fragmentary cross-sectional views of alternative structures 300, 400, 500, 200′, 300′, 400′, and 500′, respectively. The alternative structures 300, 400, 500, 200′, 300′, 400′, and 500′ are fabricated according to method 100 in FIG. 1 described above. Features at various fabricating stages, such as trenches 256 (including the first type trench 256-1 and the second type trench 256-2) may be similar as those described above.

Referring to FIG. 10, compared to the embodiments represented by FIGS. 2-9, differences in fabrication and structure include the follows. The metal liner 272 as in FIG. 9 is not formed in the structure 300 in FIG. 10. In other words, operations at block 114 are omitted in fabricating the structure 300. In the structure 300, the source/drain contact plugs 274′ are directly deposited on the metal silicide residual layer 270′ and the second silicide layer 270. The first source/drain contact 276-1 includes the source/drain contact plug 274′, the first silicide layer 266, the metal phosphide layer 268, the second silicide layer 270, the metal phosphide residual layer 268′, and the metal silicide residual layer 270′ in the first type trench 256-1. The second source/drain contact 276-2 includes the source/drain contact plug 274′, the metal phosphide layer 268, the second silicide layer 270, the metal phosphide residual layer 268′, and the metal silicide residual layer 270′ in the second type trench 256-2.

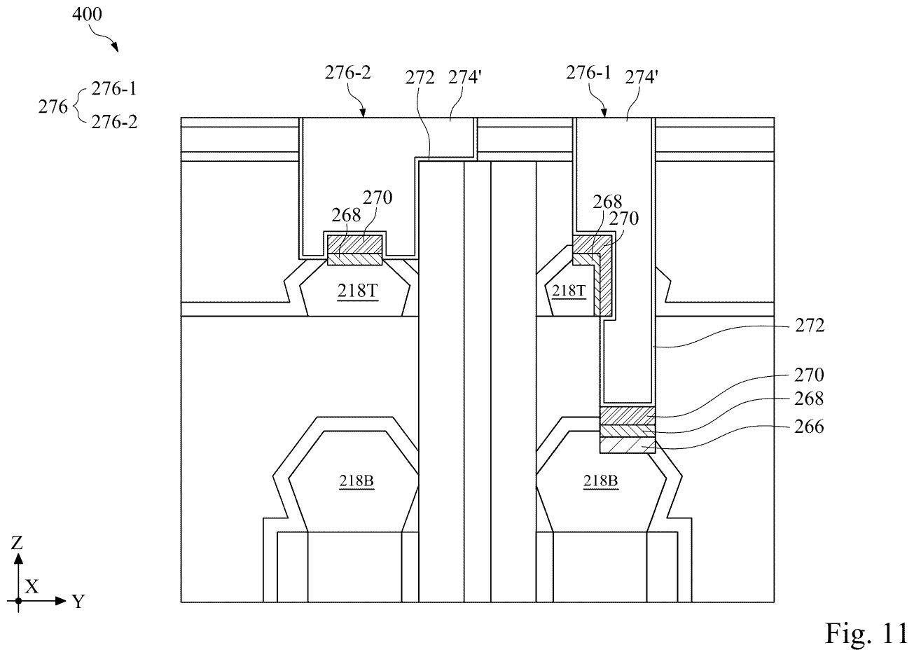

Referring to FIG. 11, compared to the embodiments represented by FIG. 9, differences in fabrication and structure include the follows. The metal phosphide residual layer 268′ and the metal silicide residual layer 270′ as in FIG. 9 are not included in the structure 400 in FIG. 11. The metal liner 272 is directly deposited on the second silicide layer 272 and the surfaces of the dielectric materials in the trenches 256. Lack of sidewall residue (e.g., the metal phosphide residual layer 268′ and the metal silicide residual layer 270′) may be a result of selectivity (e.g., epitaxy-to-dielectric selectivity) of the deposition processes at blocks 110 and 112, and/or third pull-back process(es) (e.g., a sidewall pull-back process) at blocks 110 and/or 112. The third pull-back process(es) may replace the first and second pull-back processes described above, using similar methods as the first and second pull-back processes and removing a majority (e.g., greater than about 95%) to all of the metal phosphide, the second metal, and/or the metal silicide from surfaces of the dielectric materials in the trenches 256 of the structure 400. After the third pull-back process(es), the metal phosphide, the second metal, and/or the metal silicide on the surfaces of the dielectric materials in the trenches 256 are negligible. The third pull-back process(es) may be after the deposition processes at blocks 110 and/or 112. In FIG. 11, the first source/drain contact 276-1 includes the source/drain contact plug 274′, the metal liner 272, the first silicide layer 266, the metal phosphide layer 268, and the second silicide layer 270 in the first type trench 256-1. The second source/drain contact 276-2 includes the source/drain contact plug 274′, the metal liner 272, the metal phosphide layer 268, and the second silicide layer 270 in the second type trench 256-2.

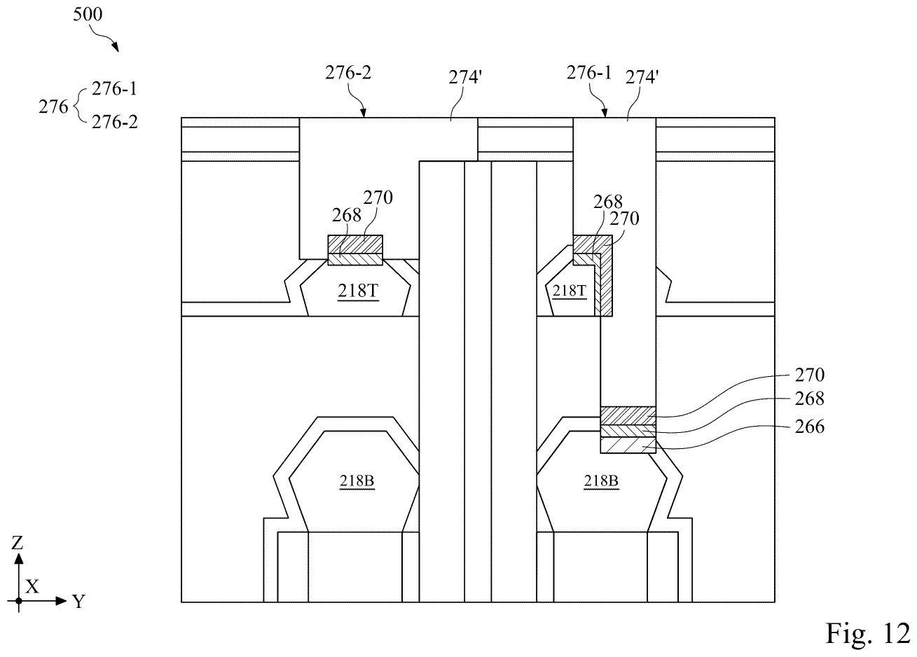

Referring to FIG. 12, compared to the embodiments represented by FIG. 11, differences in fabrication and structure include the follows. The metal liner 272 as in FIG. 11 is not formed in the structure 500 in FIG. 12. In other words, operations at block 114 are omitted in fabricating the structure 500. In the structure 500, the source/drain contact plugs 274′ are directly deposited on the second silicide layer 270 and on sidewalls of the dielectric materials in the trenches 256. The first source/drain contact 276-1 includes the source/drain contact plug 274′, the first silicide layer 266, the metal phosphide layer 268, and the second silicide layer 270 in the first type trench 256-1. The second source/drain contact 276-2 includes the source/drain contact plug 274′, the metal phosphide layer 268, and the second silicide layer 270 in the second type trench 256-2.

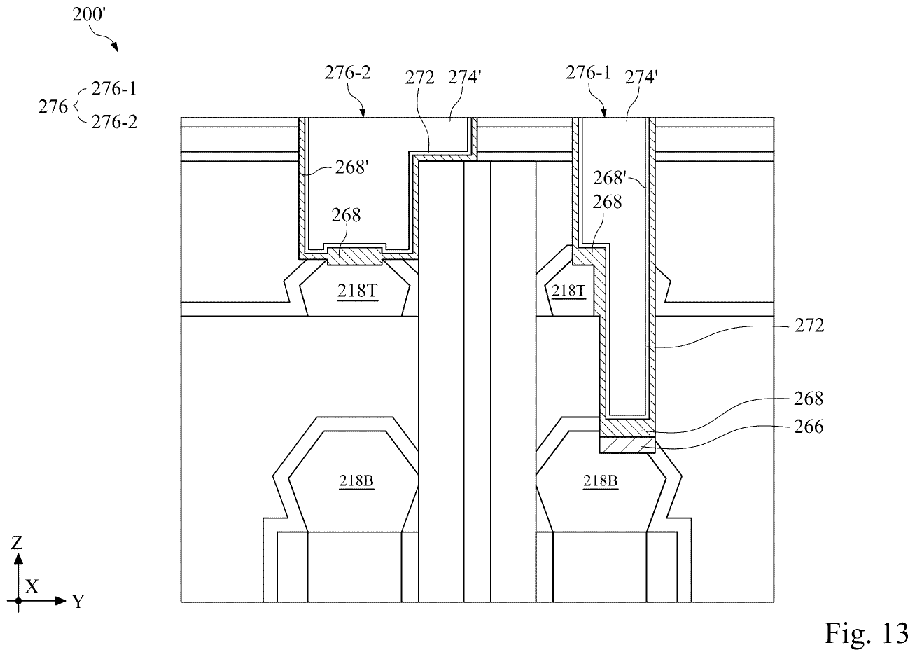

The structures 200′, 300′, 400′, and 500′ in FIGS. 13-16 generally resemble the structures 200, 300, 400, and 500 in FIGS. 9-12, respectively, with the exception that the second silicide layer 270 and the metal silicide residual layer 270′ are not formed. In other words, operations at block 112 is omitted in forming the structures 200′, 300′, 400′, and 500′.

Referring to FIG. 13, compared to the embodiments represented by FIG. 9, additional differences in fabrication and structure include the follows. A thickness of the metal phosphide layer 268 is about 3 nm to about 10 nm. A ratio of the thickness of the metal phosphide layer 268 to a thickness of the first silicide layer 266 is about 0.5 to about 3. The metal phosphide residual layer 268′ may have a thickness of equal to or less than about 2 nm. The metal liner 272 is directly deposited on the metal phosphide layer 268 and the metal phosphide residual layer 268′. The first source/drain contact 276-1 includes the source/drain contact plug 274′, the metal liner 272, the first silicide layer 266, the metal phosphide layer 268, and the metal phosphide residual layer 268′ in the first type trench 256-1. The second source/drain contact 276-2 includes the source/drain contact plug 274′, the metal liner 272, the metal phosphide layer 268, and the metal phosphide residual layer 268′ in the second type trench 256-2.

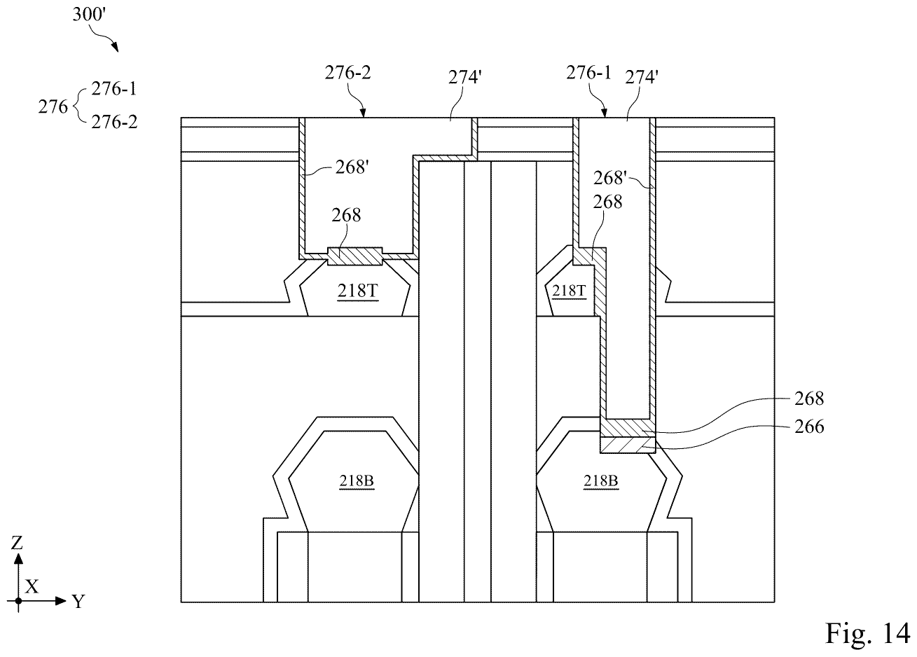

Referring to FIG. 14, compared to the embodiments represented by FIG. 13, differences in fabrication and structure include the follows. The metal liner 272 as in FIG. 13 is not formed in the structure 300′ in FIG. 14. In other words, operations at block 114 are omitted in fabricating the structure 300′. In the structure 300′, the source/drain contact plugs 274′ are directly deposited on the metal phosphide layer 268 and the metal phosphide residual layer 268′ in the trenches 256. The first source/drain contact 276-1 includes the source/drain contact plug 274′, the first silicide layer 266, the metal phosphide layer 268, and the metal phosphide residual layer 268′ in the first type trench 256-1. The second source/drain contact 276-2 includes the source/drain contact plug 274′, the metal phosphide layer 268, and the metal phosphide residual layer 268′ in the second type trench 256-2.

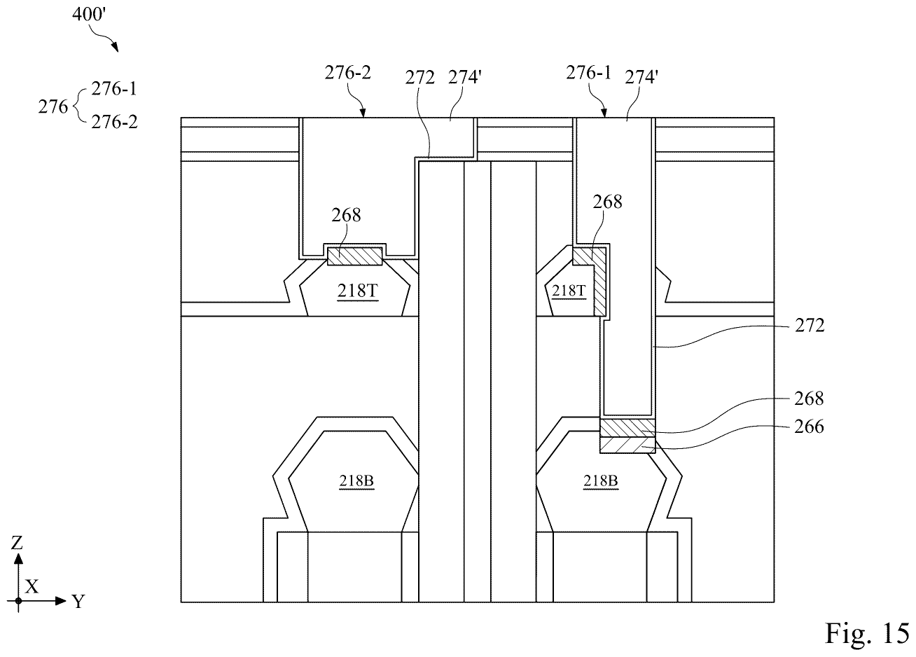

Referring to FIG. 15, compared to the embodiments represented by FIG. 13, differences in fabrication and structure include the follows. The metal phosphide residual layer 268′ as in FIG. 13 is not included in the structure 400′ in FIG. 15. The metal liner 272 is directly deposited on the metal phosphide layer 268 and the surfaces of the dielectric materials in the trenches 256 of the structure 400′. Lack of sidewall residue (e.g., the metal phosphide residual layer 268′) may be a result of selectivity (e.g., epitaxy-to-dielectric selectivity) of the deposition processes at block 110, and/or a fourth pull-back process (e.g., a sidewall pull-back process) at block 110. The fourth pull-back process may replace the first pull-back process as described above, using similar methods as the first pull-back process, and removing a majority (e.g., greater than about 95%) to all of the metal phosphide from surfaces of the dielectric materials in the trenches 256 of the structure 400′. After the fourth pull-back process, the metal phosphide on the surfaces of the dielectric materials in the trenches 256 are negligible. The fourth pull-back process may be after the deposition processes at block 110. In FIG. 15, the first source/drain contact 276-1 includes the source/drain contact plug 274′, the metal liner 272, the first silicide layer 266, and the metal phosphide layer 268 in the first type trench 256-1. The second source/drain contact 276-2 includes the source/drain contact plug 274′, the metal liner 272, and the metal phosphide layer 268 in the second type trench 256-2.

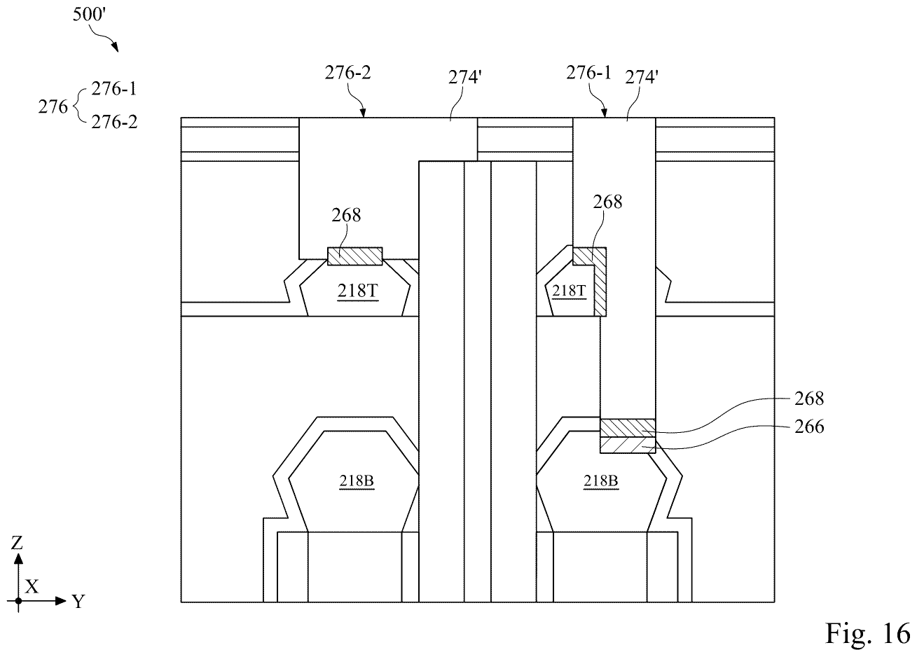

Referring to FIG. 16, compared to the embodiments represented by FIG. 15, differences in fabrication and structure include the follows. The metal liner 272 as in FIG. 15 is not formed in the structure 500′ in FIG. 16. In other words, operations at block 114 are omitted in fabricating the structure 500′. In the structure 500′, the source/drain contact plugs 274′ are directly deposited on the metal phosphide layer 268 and the surfaces of the dielectric materials in the trenches 256. In FIG. 16, the first source/drain contact 276-1 includes the source/drain contact plug 274′, the first silicide layer 266, and the metal phosphide layer 268 in the first type trench 256-1. The second source/drain contact 276-2 includes the source/drain contact plug 274′, and the metal phosphide layer 268 in the second type trench 256-2.

In FIGS. 9-16, the first silicide layer 266 may be omitted (i.e., not formed). In such embodiments, the metal phosphide layer 268 is formed directly on the bottom source/drain feature 218B. In such embodiments, without the first the silicide layer 266 therebetween, constituents (e.g., silicon, germanium) of the bottom source/drain feature 218B may react with the metal phosphide during the deposition process at block 110, thus composition of the metal phosphide layer 268 on the bottom source/drain feature 218B may be different from the composition of the metal phosphide layer 268 on the top source/drain feature 218B as described above. Without forming the first silicide layer 266, the metal phosphide layer 268 on the bottom source/drain feature 218B may include the metal phosphide described above and further include a metal germosilicide phosphide (MₓSi_{y}Ge_{g}P_{z}) of the first metal. In MₓSi_{y}Ge_{g}P_{z}, g may be equal to or greater than zero, and equal to or less than about 30. A ratio of a sum of g and y to x may be equal to or less than about 2 (i.e., (g+y)/x≤2). A ratio of z to x may be equal to or less than about 1.

Although FIGS. 2-15 illustrate stacked transistor structures having GAA transistors, other examples of semiconductor devices (e.g., multigate devices, stacked transistor structures having any combination of transistors, such as planar, FinFET, nanosheet, and nanowire transistors) may benefit from aspects of the present disclosure.

Although not intended to be limiting, one or more embodiments of the present disclosure provide many benefits to a semiconductor structure. For example, by depositing the metal precursor and the phosphorus-containing precursor to form the metal phosphide layer, resistance of the source/drain contact may be reduced. In addition, by forming a silicide layer over the metal phosphide layer, additional dipoles are formed from the silicide layer and the metal phosphide layer, which may reduce the SBH at the interface of the source/drain feature and the source/drain contact and reduce the resistance of the source/drain contact. Thus, the overall performance of the semiconductor device may be improved.

In one exemplary aspect, the present disclosure is directed to a method. The method includes providing a structure. The structure includes a bottom source/drain feature, a bottom contact etch stop layer (CESL) disposed over the bottom source/drain feature, a bottom interlayer dielectric (ILD) layer disposed over the bottom CESL, a top source/drain feature disposed over the bottom ILD layer, a top CESL disposed over the top source/drain feature and the bottom ILD layer, and a top ILD layer disposed over the top source/drain feature. A thickness of the bottom CESL is less than a thickness of the bottom ILD layer, a thickness of the top CESL is less than a thickness of the top ILD layer. The method further includes forming a trench extending in the top ILD layer and the bottom ILD layer, the trench exposes the top source/drain feature and the bottom source/drain feature. The method further includes depositing a metal precursor and a phosphorus-containing precursor in the trench, thereby forming a metal phosphide layer over the top source/drain feature and the bottom source/drain feature, and forming a metal fill layer in the trench and over the metal phosphide layer.

In some embodiments, the method further includes forming a silicide layer over the metal phosphide layer. In some embodiments, the metal phosphide layer includes a first metal having a first electronegativity, the silicide layer includes a second metal having a second electronegativity greater than the first metal. In some embodiments, before depositing the metal precursor and the phosphorus-containing precursor in the trench, the method further includes forming a silicide layer over the bottom source/drain feature but not the top source/drain feature, the silicide layer is disposed between the metal phosphide layer and the bottom source/drain feature. In some embodiments, the metal precursor includes a metal halide, a coordination complex, or a combination thereof, and ligands of the coordination complex include tris-alkylcyclopentadienyl, bis-alkylcyclopentadienyl-alkylamidinate, tris-alkyl amidinate, tris-(alkylacac), tris[N,N-bis(trimethylsilyl)amide], tetrakis(dialkylamido), cyclopentadienyl metal chlorides, or a combination thereof. In some embodiments, the phosphorus-containing precursor includes P, PH₃, P₂H₄, PₙHₙ₊₂, phosphorus, phosphines, phosphanes, phosphenes, P(SiH₃)₃, P(Si(CₘH₂ₘ₊₁)₃)₃, P(CₓH₂ₓ₊₁)₃, P(C_{y}H_{2y-1})₃, triphenyl phosphine, tri(2-furyl)phosphine, white phosphorus, or a combination thereof, n is equal to or less than about 3, m is equal to or less than about 8, x is equal to or less than about 8, and y is equal to or greater than about 5 and equal to or less than about 8. In some embodiments, depositing the metal precursor and the phosphorus-containing precursor is at a temperature of about 100 degree C. to about 600 degree C. In some embodiments, before forming the metal fill layer, the method further includes depositing a metal liner in the trench and over the metal phosphide layer, the metal fill layer is disposed over the metal liner. In some embodiments, the metal phosphide layer further includes silicon.

In another exemplary aspect, the present disclosure is directed to a method. The method includes providing a structure. The structure includes an active region including a channel region and a source/drain region adjacent to the channel region, a gate structure over the channel region, a source/drain feature over the source/drain region, a contact etch stop layer (CESL) over the source/drain feature, and an interlayer dielectric (ILD) layer over the CESL. The method further includes forming a trench in the CESL and the ILD layer to expose the source/drain feature providing a metal precursor and a phosphorus source in the trench, thereby forming a metal phosphide layer over the source/drain feature forming a silicide layer on the metal phosphide layer, and forming a metal fill layer in the trench.

In some embodiments, the metal precursor and the metal phosphide layer include a first metal, and the silicide layer includes a second metal different from the first metal. In some embodiments, the first metal is an early transition metal. In some embodiments, the metal precursor includes a metal halide, a coordination complex, or a combination thereof. In some embodiments, the metal phosphide layer includes MₘPₙ, MₓSi_{y}P_{z}, or a combination thereof, m is equal to or greater than about 1 and equal to or less than about 15, n is greater than zero and equal to or less than about 12, x is equal to or greater than about 1 and equal to or less than about 15, y is equal to or greater than zero and equal to or less than about 30, and z is greater than zero and equal to or less than about 12. In some embodiments, a ratio of y to x is equal to or less than about 2, and a ratio of n to m and a ratio of z to x are equal to or less than about 1. In some embodiments, the metal phosphide layer is further formed on sidewalls of the trench.

In yet another exemplary aspect, the present disclosure is directed to a semiconductor structure. The semiconductor structure includes a bottom transistor and a top transistor disposed above the bottom transistor. The bottom transistor includes a bottom source/drain feature and a bottom dielectric layer disposed over the bottom source/drain feature, the top transistor includes a top source/drain feature and a top dielectric layer disposed over the top source/drain feature. The semiconductor structure further includes a contact feature extending through the top and bottom dielectric layers, and metal phosphide layers and metal silicide layers disposed between the top source/drain feature and the contact feature and between the bottom source/drain features and the contact feature. An electrical conductivity of the contact feature is greater than electrical conductivities of the top and bottom source/drain features. The metal phosphide layer includes a first metal and phosphorus, the metal silicide layer includes a second metal different from the first metal.

In some embodiments, the metal silicide layers are disposed between the metal phosphide layers and the contact feature. In some embodiments, the first metal includes Zr, Hf, Sc, Y, Yb, La, Er, Dy, Ce, or a combination thereof, and the second metal includes Ti, Zr, V, Nb, Ta, Mo, W, Re, Ru, Os, Ni, Pd, Pt or Zn, or a combination thereof. In some embodiments, an electronegativity of the second metal is greater than an electronegativity of the first metal.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
providing a structure comprising:
a bottom source/drain feature,
a bottom contact etch stop layer (CESL) disposed over the bottom source/drain feature,
a bottom interlayer dielectric (ILD) layer disposed over the bottom CESL, wherein a thickness of the bottom CESL is less than a thickness of the bottom ILD layer,
a top source/drain feature disposed over the bottom ILD layer,
a top CESL disposed over the top source/drain feature and the bottom ILD layer, and
a top ILD layer disposed over the top source/drain feature, wherein a thickness of the top CESL is less than a thickness of the top ILD layer;
forming a trench extending in the top ILD layer and the bottom ILD layer, wherein the trench exposes the top source/drain feature and the bottom source/drain feature;
depositing a metal precursor and a phosphorus-containing precursor in the trench, thereby forming a metal phosphide layer over the top source/drain feature and the bottom source/drain feature; and
forming a metal fill layer in the trench and over the metal phosphide layer.

2. The method of claim 1, further comprising forming a silicide layer over the metal phosphide layer.

3. The method of claim 2, wherein the metal phosphide layer comprises a first metal having a first electronegativity,
wherein the silicide layer comprises a second metal having a second electronegativity greater than the first metal.

4. The method of claim 1, before depositing the metal precursor and the phosphorus-containing precursor in the trench, further comprising forming a silicide layer over the bottom source/drain feature but not the top source/drain feature,
wherein the silicide layer is disposed between the metal phosphide layer and the bottom source/drain feature.

5. The method of claim 1, wherein the metal precursor comprises a metal halide, a coordination complex, or a combination thereof, and
wherein ligands of the coordination complex comprise tris-alkylcyclopentadienyl, bis-alkylcyclopentadienyl-alkylamidinate, tris-alkyl amidinate, tris-(alkylacac), tris[N,N-bis(trimethylsilyl)amide], tetrakis(dialkylamido), cyclopentadienyl metal chlorides, or a combination thereof.

6. The method of claim 1, wherein the phosphorus-containing precursor comprises P, PH₃, P₂H₄, PₙHₙ₊₂, phosphorus, phosphines, phosphanes, phosphenes, P(SiH₃)₃, P(Si(CₘH₂ₘ₊₁)₃)₃, P(CₓH₂ₓ₊₁)₃, P(C_{y}H_{2y-1})₃, triphenyl phosphine, tri(2-furyl)phosphine, white phosphorus, or a combination thereof,
wherein n is equal to or less than about 3, m is equal to or less than about 8, x is equal to or less than about 8, and y is equal to or greater than about 5 and equal to or less than about 8.

7. The method of claim 1, wherein depositing the metal precursor and the phosphorus-containing precursor is at a temperature of about 100 degree C. to about 600 degree C.

8. The method of claim 1, wherein before forming the metal fill layer, further comprising depositing a metal liner in the trench and over the metal phosphide layer,
wherein the metal fill layer is disposed over the metal liner.

9. The method of claim 1, wherein the metal phosphide layer further comprises silicon.

10. A method comprising:
providing a structure comprising:
an active region comprising a channel region and a source/drain region adjacent to the channel region,
a gate structure over the channel region,
a source/drain feature over the source/drain region,
a contact etch stop layer (CESL) over the source/drain feature, and
an interlayer dielectric (ILD) layer over the CESL;
forming a trench in the CESL and the ILD layer to expose the source/drain feature;
providing a metal precursor and a phosphorus source in the trench, thereby forming a metal phosphide layer over the source/drain feature;
forming a silicide layer on the metal phosphide layer; and
forming a metal fill layer in the trench.

11. The method of claim 10, wherein the metal precursor and the metal phosphide layer comprise a first metal, and
wherein the silicide layer comprises a second metal different from the first metal.

12. The method of claim 11, wherein the first metal is an early transition metal.

13. The method of claim 10, wherein the metal precursor comprises a metal halide, a coordination complex, or a combination thereof.

14. The method of claim 10, wherein the metal phosphide layer comprises MₘPₙ, MₓSi_{y}P_{z}, or a combination thereof,
wherein m is equal to or greater than about 1 and equal to or less than about 15, n is greater than zero and equal to or less than about 12, x is equal to or greater than about 1 and equal to or less than about 15, y is equal to or greater than zero and equal to or less than about 30, and z is greater than zero and equal to or less than about 12.

15. The method of claim 14, wherein a ratio of y to x is equal to or less than about 2, and
wherein a ratio of n to m and a ratio of z to x are equal to or less than about 1.

16. The method of claim 10, wherein the metal phosphide layer is further formed on sidewalls of the trench.

17. A semiconductor structure, comprising:
a bottom transistor and a top transistor disposed above the bottom transistor, wherein the bottom transistor comprises a bottom source/drain feature and a bottom dielectric layer disposed over the bottom source/drain feature, wherein the top transistor comprises a top source/drain feature and a top dielectric layer disposed over the top source/drain feature;
a contact feature extending through the top and bottom dielectric layers, wherein an electrical conductivity of the contact feature is greater than electrical conductivities of the top and bottom source/drain features; and
metal phosphide layers and metal silicide layers disposed between the top source/drain feature and the contact feature and between the bottom source/drain features and the contact feature,
wherein the metal phosphide layer comprises a first metal and phosphorus,
wherein the metal silicide layer comprises a second metal different from the first metal.

18. The semiconductor structure of claim 17, wherein the metal silicide layers are disposed between the metal phosphide layers and the contact feature.

19. The semiconductor structure of claim 17, wherein the first metal comprises Zr, Hf, Sc, Y, Yb, La, Er, Dy, Ce, or a combination thereof, and
wherein the second metal comprises Ti, Zr, V, Nb, Ta, Mo, W, Re, Ru, Os, Ni, Pd, Pt or Zn, or a combination thereof.

20. The semiconductor structure of claim 17, wherein an electronegativity of the second metal is greater than an electronegativity of the first metal.
